(19) United States
(12) Patent Application Publication
(10) Pub. No.: US 2009/0111522 A1
(43) Pub. Date: Apr. 30, 2009

(54) Smart Card and Method for Manufacturing Said Card

(76) Inventor: Javier Canis Robles, Madrid (ES)

Correspondence Address: BRINKS HOFER GILSON & LIONE/SanDisk, P.O. BOX 10395, CHICAGO, IL, 60610, US

(21) Appl. No.: 12/224,772

(22) PCT Filed: Mar. 9, 2006
(86) PCT No.: PCT/ES2006/000113

§ 371 Date: Oct. 10, 2008

(51) Int. Cl. H04M 1/00; H01L 21/20

(52) U.S. Cl. 455/558; 438/106; 257/E21.09; 257/679

(57) ABSTRACT

The present invention relates to a smart card provided with an integrated circuit for identifying a user, storing and exchanging information with an electronic device, such as for example a mobile telephone, a personal computer, etc. The smart card is provided with additional communication contacts apart from those that are conventionally arranged on the integrated circuit itself, and it incorporates means allowing one of these cards provided with additional contacts to be able to be used without any problems in card readers that do not support these additional contacts. The present invention consists of the fact that the arrangement of these new contacts is not located on the surface of the smart card, plastic body of the card or microchip, preventing the conductive parts of the reader which are in contact with the smart card from causing any type of malfunction thereof. The invention also relates to a method of manufacturing the previously mentioned smart card.

### OBJECT OF THE INVENTION

The object of the present invention is a smart card provided with an integrated circuit for identifying a user, storing and exchanging information with an electronic device, for example with a mobile telephone, a personal computer, etc.

One of the objects of the invention relates to a smart card provided with additional communication contacts apart from those that are conventionally arranged in the integrated circuit itself, such that the card incorporates means allowing the card to be used without any problems in card readers which do not support these additional contacts, i.e. the card is compatible with card readers of any type.

A method of manufacturing the previously mentioned smart card is also an object of the invention.

### BACKGROUND OF THE INVENTION

A smart card usually consists of a plastic part and another metallic part where the contacts of the card are located, such contacts being internally connected to an integrated circuit. This type of cards, which are also known as SIM (Subscriber Identity Module) cards, are used in a wide variety of electronic devices, such as mobile telephones, personal computers, PDAs, among other tasks for identifying a user and for storing and exchanging information.

When the smart card is introduced in a reader, for example in a mobile telephone, the contacts of the smart card coincide with the contacts of the reader of the telephone, producing an electric communication between them. Some readers of this type of cards are described for example in patent documents U.S. Pat. No. 6,305,960 and U.S. Pat. No. 6,398,572, which describe the arrangement of the reading terminals of the card reader in contact with the terminals of a card.

Due to the significant evolution of smart card technology and the increase of its processing capacity, the number of contacts of a standard smart card implies a disadvantage for making use of the smart card's potential.

To solve this drawback, it is possible to define new contacts or new contact areas which allow increasing the communication capacity between the smart card and the device it is connected to. There is a major drawback with this increase of contacts, which is the incompatibility with readers that do not support this increase of contacts, not insofar as these readers cannot communicate through the new contacts the smart card has, which is obvious, but in that it is possible that these readers may not even be able to operate with the cards with additional contacts by using the old contacts, since the support for the card that the reader has, which in many cases is a conductive material, could short-circuit the new contacts of the card, causing malfunction of or damage to the card.

### DESCRIPTION OF THE INVENTION

The present invention resolves in a fully satisfactory manner the drawbacks brought about due to the incompatibility between smart cards having new contacts and readers that do not support these new contacts.

One of the aspects of the present invention consists of a smart card provided with additional contacts or terminals, i.e. electrical contacts arranged in any suitable part of the plastic support of the card as additional contacts to those arranged in the integrated circuit. More specifically, these new contacts are not in the same plane of the surface of the smart card, plastic body of the card or microchip, but rather in a different plane such that they cannot accidentally make contact with any element of the card reader once the card is connected to the reader The new terminals or additional contacts of the card according to the invention can be arranged inside a cavity made in the card itself, such that with this contact arrangement, conductive parts of the reader which are in contact with the smart card are prevented from causing any type of malfunction of such card.

The new contacts can be arranged in any part of the smart card, both in the plastic body thereof and in the microchip itself.

Thus, a first aspect of the invention relates to a smart card formed by a support made of a non-conductive material, such as a plastic for example, having an upper face and a lower face as well as an integrated circuit attached to said support and electrical surface terminals arranged on the upper face of the support, which are electrically communicated with said integrated circuit and are used for the electrical connection of the card with a reading device, for example a mobile telephone, for storing and exchanging data. The card is characterized in that it comprises at least one inner electrical terminal arranged between said upper and lower faces of the support, which is electrically communicated with said integrated circuit and is accessible from outside the support.

The support of the card has a hole or opening in correspondence with each inner electrical terminal, such that such terminal is accessible from outside the card. These holes are preferably in the upper face of the card, but they may also be on the other face of the card or they may be in the upper and lower face so as to provide access to the inner terminals indistinctly from both faces. In turn, these holes or openings may be in any part of the support of the card, they may even be between the surface terminals of the integrated circuit

The card further has electrical conductors embedded in the support of the card, communicating each inner terminal with the integrated circuit

A second aspect of the invention relates to a card reader able to operate together with the previously described smart card. This card reader has electrical connecting terminals known in the state of the art and is characterized in that at least one of its terminals has a part that is located at a greater height or that is longer than the remaining terminals, such that when the card with additional terminals is connected to this card reader, this terminal can be inserted into the previously mentioned openings and come into contact with an inner terminal of the card. This aspect of the invention also relates to an electronic device, such as a mobile telephone or personal computer for example, incorporating the previously mentioned card reader with additional contacts at a greater height than the remaining contacts.

A third aspect of the invention relates to a method of manufacturing a smart card, in which an integrated circuit is attached or assembled in a support of the card in the form of a sheet, and therefore defines an upper face and a lower face. In this method, surface terminals arranged in said upper face of the support are connected to said integrated circuit. The method comprises locating between the upper and lower faces of said support at least one inner connecting terminal and communicating said inner terminal with the integrated circuit by means of a conductive element, and in which an opening is provided in said support in correspondence with said inner terminal, such that such terminal is accessible from outside the support.

The support of the card may be manufactured of several superimposed layers. An intermediate layer can thus be available in which a cavity has been made to house the integrated circuit and on which a layer of conductive material is applied by means of any technique known by a person skilled in the art, forming the additional inner terminals, inner contacts for the integrated circuit and conducting tracks connecting said terminals and contacts. An upper layer in turn provided with a window intended for receiving the integrated circuit and its terminals, as well as openings arranged according to the location of the inner terminals are additionally obtained in the method. The intermediate and upper layers overlap and are attached to one another by means of known techniques, and then the integrated circuit is connected in the mentioned cavity through the window, making it come into contact with the inner contacts arranged in the intermediate layer. Alternatively, the openings of the upper layer may be made after attaching the upper and intermediate layers.

### DESCRIPTION OF THE DRAWINGS

To complement the description being made and for the purpose of aiding to better understand the features of the invention according to a preferred practical embodiment thereof, a set of drawings is attached as an integral part of said description in which the following has been shown with an illustrative and non-limiting character:

FIG. 1 shows several perspective views of the smart card object of the invention. In FIG. (1a), the openings and inner terminals are located in a part of the support adjacent to the surface terminals of the integrated circuit; in FIG. (1b) they are located right on the edge of the support; and in FIG. (1c) they are located in the metallic area formed by the surface terminals of the chip.

FIG. 2 shows in FIG. (2a) an upper plan view of the microchip in which the surface terminals thereof can be seen, and FIG. (2b) shows a lower plan view of the microchip in which the inner contacts of the microchip can be seen.

FIG. 3 shows a plan view of the intermediate layer of the card, in which the inner terminals and conductors communicating them with the integrated circuit can be seen.

FIG. 4 shows a plan view of an upper layer.

FIG. 5 shows a schematic sectional view of a smart card according to an embodiment of the invention, where the inner terminals do not coincide with the integrated circuit. The sectional view is taken along a section line that is longitudinal to the card passing through one of the inner terminals.

FIG. 6 shows a perspective view of respective modules with surface contacts and openings.

FIG. 7 shows a schematic sectional view of a smart card according to an embodiment of the invention, in which the inner terminals coincide with the integrated circuit.

### PREFERRED EMBODIMENT OF THE INVENTION

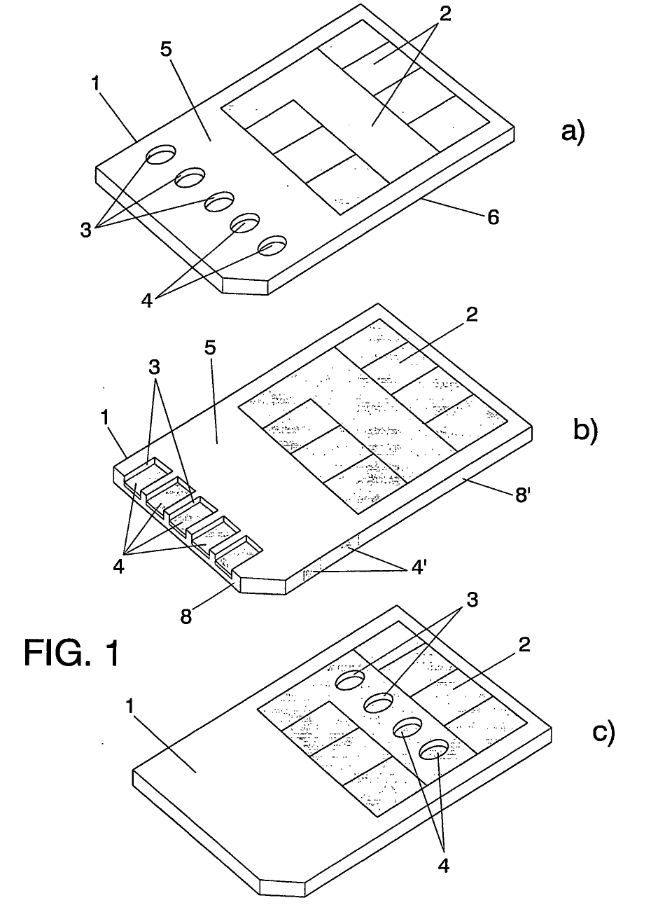

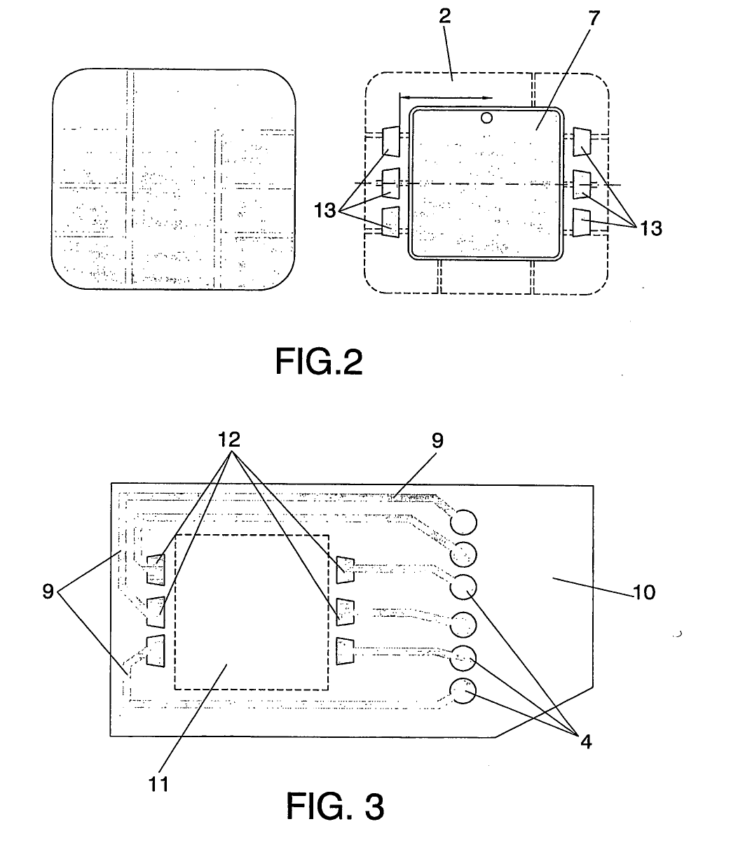

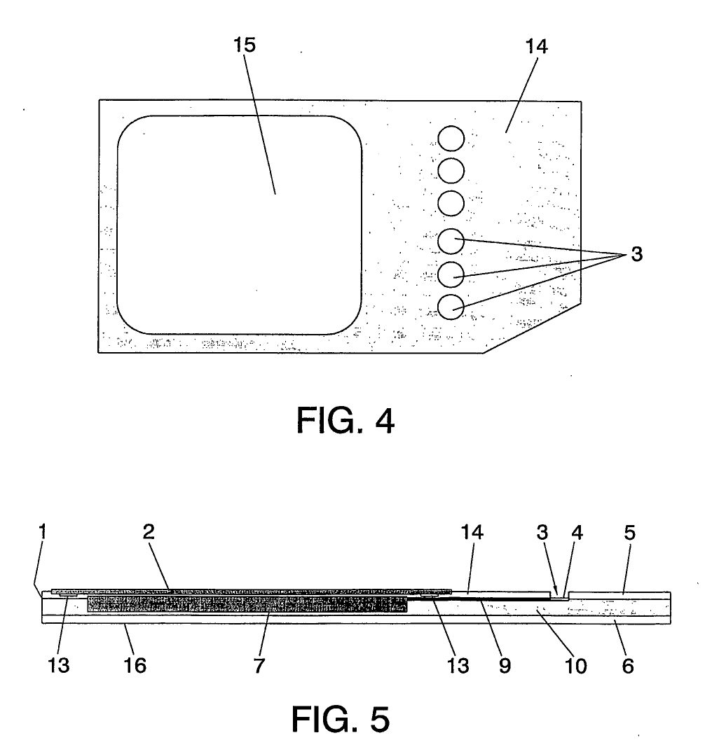

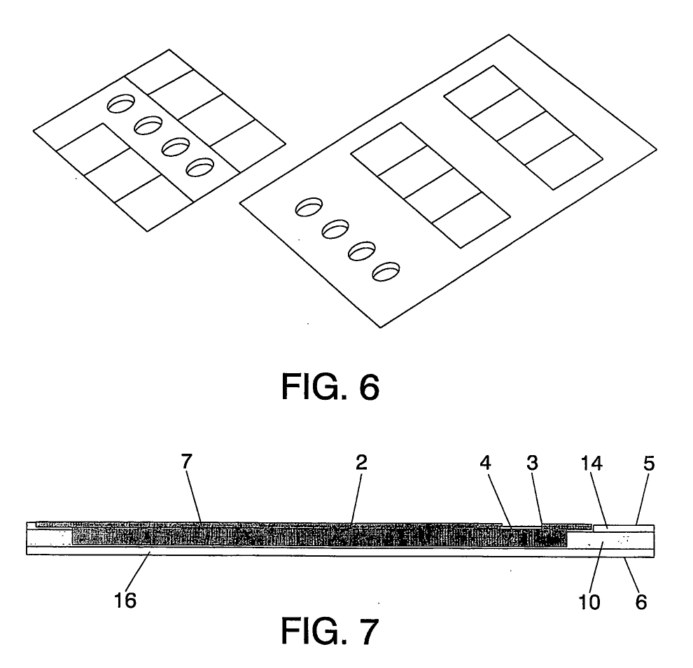

FIG. 1 shows a SIM card-like smart card made up of a support (1) or body of the card generally made of plastic, in which an upper face (5) and a lower face (6) are defined, as can be seen more clearly in FIGS. 5 and 7. The electrical surface terminals (2) of the integrated circuit or microchip (7) are arranged in one of the faces of the support (1), for example in the upper face (5), in a manner that is known for this type of cards.

The smart card of the invention is characterized by having at least one inner electrical terminal (4) arranged between the upper face (5) and the lower face (6) of the support (1), said inner terminal (4) being electrically communicated with the integrated circuit (7) by means of an electrical connection (9). The support (1) has an opening (3) in correspondence with each of the existing inner terminals (4), such that such terminals are accessible from outside the card and allowing for example that the terminals of a card reading device (not shown), can form an electrical connection with said inner terminals (4) during the use of the card.

In the specific embodiment of FIG. 1a, there are five inner terminals (4) arranged aligned and parallel to one of the edges of the card, though these terminals may logically be arranged in any other arrangement that is considered appropriate, for example in a mesh pattern. Similarly, the card has five openings (3) in correspondence with each terminal (4) such that the latter are accessible from the upper face (5).

In other embodiments of the invention, the openings (3) can be arranged in the face opposite to the face where the surface terminals (2) are arranged, in this case the lower face (6), or openings can even be arranged in both faces of the support so as to provide access to the inner terminals (4) indistinctly from both faces. With this arrangement of the openings (4), the card can be used with a particular card reader which requires accessing the inner terminals (4) from either position.

In the case of FIG. 1a, the openings (3) are elliptical shaped, though they may naturally have any other shape, for example polygonal, square, rectangular or circular, etc.

The inner terminals (4) and the corresponding openings (3) may be located in any part of the card that is considered appropriate. In the case of FIG. 1a, the inner terminals (3) are arranged in an area of the support (1) adjacent to the terminals (2). In the case of the FIG. 1b, the inner terminals (4) and the openings (3) are rectangular and are located in one of the smaller edges of the rectangular body of the card, such that the openings (4) reach not only the upper face (5) but also extend to one of the side walls (8) of the support of the card. The inner terminals (4) are therefore not only accessible from the upper face (5), but they are also accessible in this embodiment from the aforementioned side wall (8). In other embodiments, the inner terminals (4) can be accessible from only one or more of the side walls or edges (8),(8′) of the support (1) of the card, maintaining the location of such terminals between the upper and lower faces (5),(6) according to the invention. The inner terminals (4′) of FIG. 1b show this possibility.

Some of the inner terminals (4) may even be located in the metal parts area formed by the surface terminals (2) of the integrated circuit or microchip. This possibility is shown in the embodiment of FIG. 1c and is especially advantageous because the inner terminals (4) can be directly connected to the microchip without the need for electrical connections (9) inside the support (1).

The support (1) of the card can be formed by several layers or sheets of plastic. FIGS. 3, 5 and 7 show an intermediate layer (10) forming part of the support (1) and which, according to FIG. 3, has the inner terminals (4) as well as first contacts (12) for the integrated circuit (7) on one of its faces. The aforementioned terminals (4) and contacts (12) are electrically connected by means of respective electrical conductors (9), having the form of conducting tracks. These terminals, contacts or conductors can be made with any suitable type of conductive material, such as a metal, conductive ink or silver ink.

A cavity (11) intended for receiving the integrated circuit (7) and its surface terminals (2) has been made in the intermediate layer (10), the integrated circuit (7) having second contacts (13) with an arrangement corresponding to that of the first contacts (12) existing in the intermediate layer (10), such that when the integrated circuit is assembled in the cavity (11) during the manufacture of the card, the first and second contacts (13) mutually come into electrical contact and the integrated circuit is accordingly connected with the inner terminals (9).

The structure formed by the intermediate layer (10) and the integrated circuit (7) is covered by an upper layer (14) to which end this layer (14) is superimposed and adhered onto the intermediate layer (10) by means of any known technique. The upper layer (14) has openings (3) which will provide access to the inner terminals (4), as well as a window (15) with a shape and size corresponding to the area occupied by the surface terminals (2). These openings (3) and window (15) can be made in the upper layer (14) before or after they are attached to the intermediate layer (10). Once the two layers are attached, the microchip is placed in the cavity (11) through the window (15), making the contacts (12) and (13) come into contact, the integrated circuit being embedded, at least for the most part, inside the support (1).

The complete structure of the smart card can be seen in the sectional view of FIG. 5, where a lower layer (16) closes the card at its lower face. The lower layer (16) can alternatively be dispensed with, making the intermediate layer (10) thicker, thereby having a structure formed only by the upper and intermediate layers. FIG. 5 shows how the location of the inner terminal (4) is such that it is arranged in an intermediate plane of the upper and lower faces (5),(6).

With this arrangement of terminals, the smart card of the invention can be used in card readers that are not compatible with this type of cards with additional terminals, given that it prevents the risk of these terminals accidentally coming into contact with any metallic part of the reader. A smart card reader able to communicate with a card with additional terminals has reading terminals at different heights, such that some of them will be adapted to make contact with the surface terminals (2) and others with the inner terminals (4).

FIG. 7 consists of a view similar to that of FIG. 5, in which the inner terminals (4) are located between the surface terminals (2) according to the embodiment of FIG. 1b. In this case, the inner terminals (4) are also located in an intermediate plane between the upper and lower faces (5),(6), although they are closer to the upper face (5) given that they are in direct contact with the integrated circuit (7).

Several practical embodiments of the invention are described in the attached dependent claims.

In view of this description and set of drawings, a person skilled in the art may understand that the embodiments of the invention which have been described can be combined in many ways within the object of the invention. The invention has been described according to several preferred embodiments thereof, but for a person skilled in the art it will be obvious that many variations can be introduced in said preferred embodiments without departing from the object of the claimed invention.

1. A smart card comprising:
a support made of a non-conductive material having an upper face and a lower face,
an integrated circuit attached to the support,
electrical terminals arranged in the upper face of the support, wherein the electrical terminals are electrically communicated with the integrated circuit, and
at least one inner electrical terminal arranged between the upper and lower faces of the support, wherein the at least one electrical inner terminal is electrically connected with the integrated circuit and is accessible from outside the support,
wherein the smart card is a SIM card, and wherein the electrical terminals and the at least one inner electrical terminal are compatible with a same type of smart card reader device.

2. The smart card according to claim 1, wherein the support has an opening in correspondence with an inner electrical terminal providing access thereto from the upper face.

3. The smart card according to claim 1, wherein the support has an opening in correspondence with an inner electrical terminal providing access thereto from the lower face.

4. The smart card according to claim 1, wherein the support is made of plastic, wherein the upper and lower faces are substantially parallel to one another, and wherein the integrated circuit is embedded in a body of the support.

5. The smart card according to claim 1, further comprising electrical conductors embedded in the support and communicating each inner electrical terminal with the integrated circuit.

6. The smart card according to claim 1, wherein the upper face of the card comprises a first area with metallic parts corresponding to the electrical terminals of the integrated circuit and a second area adjacent to the first area, wherein at least one inner electrical terminal and its corresponding opening are arranged in the second area.

7. The smart card according to claim 1, wherein the upper face of the card comprises a first area with metallic parts corresponding to the electrical terminals of the integrated circuit, and wherein at least one inner electrical terminal and its corresponding opening are arranged inside the first area with metallic parts.

8. The smart card according to claim 5, wherein the inner electrical terminal and the electrical conductors are made of a material selected from: metal, conductive ink or silver ink.

9. A method of manufacturing a smart card, the method comprising:
attaching an integrated circuit to a support in a form of a sheet in which an upper face and a lower face are defined,
connecting electrical terminals arranged in the upper face to the integrated circuit,
locating between the upper and lower faces of the support at least one inner connecting terminal,
communicating the at least one inner connecting terminal with the integrated circuit with a conductive element, and
providing an opening in the support in correspondence with the inner connecting terminal such that the latter is accessible from outside the support,
wherein the electrical terminals and the at least one inner connecting terminal are compatible with a same type of smart card reader device.
